(19) United States
(12) Patent Application Publication
(10) Pub. No.: US 2020/0227277 A1
(43) Pub. Date: Jul. 16, 2020

(54) INTERPOSER WITH MANGANESE OXIDE ADHESION LAYER

(71) Applicant: CORNING INCORPORATED, Corning, NY (US)

(72) Inventors: Philip Simon Brown, Big Flats, NY (US); Yunfeng Gu, Painted Post, NY (US); Mandakini Kanungo, Painted Post, NY (US); Prantik Mazumder, Ithaca, NY (US); Rajesh Vaddi, Corning, NY (US)

(21) Appl. No.: 16/716,883

(22) Filed: Dec. 17, 2019

Related U.S. Application Data
(60) Provisional application No. 62/790,781, filed on Jan. 10, 2019.

(51) Int. Cl. H01L 21/48; H01L 23/15; H01L 23/498

(52) U.S. Cl. CPC H01L 21/486; H01L 23/15; H01L 23/49894; H01L 23/49838; H01L 23/49866

(57) ABSTRACT

A method of forming an article, comprising: forming an adhesion layer comprising MnOₓ on a glass, glass-ceramic or ceramic wafer; calcining the adhesion layer such that a first portion of the MnOₓ of the adhesion layer is chemically bonded to the wafer; depositing a metal layer on the adhesion layer; and processing the metal layer and the adhesion layer such that a portion of the MnOₓ of the adhesion layer is chemically bonded to the metal layer.

This application claims the benefit of priority to U.S. Provisional Application Ser. No. 62/790,781 filed on Jan. 10, 2019, the content of which is relied upon and incorporated herein by reference in its entirety.

### FIELD OF THE DISCLOSURE

The present disclosure relates to articles including adhesion layers, and more specifically, to manganese oxide adhesion layers for interposers that include metallized vias.

### BACKGROUND

Through-hole connections enable through silicon via (TSV) and through-glass via (TGV) based technologies that provide high packaging density, reduced signal path, wide signal bandwidth, lower packaging cost and miniaturized systems. Through-hole connections are achieved with interposers. The interposers include a substrate with a series of vias that are filled with a conductive material to permit conduction of electrical current between electronic devices patterned on opposite sides of the substrate. Copper is a preferred conductive material because of its high conductivity. In a common application, interposers provide vias with electrical connections between logic devices on one side of the interposer and memory devices on the other side of the interposer. Substrate materials for interposers include silicon and glass. Silicon has the advantage of chemical compatibility with adjacent memory and logic devices, but is also electrically lossy and inefficient from a power perspective. Glass is a low-loss electrical insulator, but the chemical inertness and low intrinsic roughness of glass pose a problem related to adhesion of the copper with the glass wall inside the vias. Lack of adhesion between copper and glass leads to reliability issues such as cracking and delamination.

Copper does not intrinsically bond well to glass due to the fundamental difference in bonding nature between the materials. Glass is a covalently bonded material, while the bonding in copper is metallic. Due to a fundamental difference in bonding mechanism, adhesion of metallic copper to glass is weak and copper-filled glass vias are structural unstable has.

### SUMMARY OF THE DISCLOSURE

According to at least one feature of the present disclosure, a method of forming an article, comprising: forming an adhesion layer comprising MnOₓ on a glass, glass-ceramic or ceramic wafer; calcining the adhesion layer such that a first portion of the MnOₓ of the adhesion layer is chemically bonded to the wafer; depositing a metal layer on the adhesion layer; and processing the metal layer and the adhesion layer such that a portion of the MnOₓ of the adhesion layer is chemically bonded to the metal layer.

According to another feature of the present disclosure, a method of forming an article, comprising: forming an adhesion layer comprising MnOₓ on a glass, glass-ceramic or ceramic wafer; depositing a metal layer comprising Cu on the adhesion layer; thermally processing the metal layer and the adhesion layer such that a portion of the MnOₓ of the adhesion layer bonds to the metal layer; and reducing a portion of the metal layer after thermally processing the metal layer and the adhesion layer.

According to another feature of the present disclosure, a method of forming an article, comprising: forming an adhesion layer comprising MnOₓ on a via surface of a via defined by a wafer; calcining the adhesion layer such that a portion of the MnOₓ of the adhesion layer is chemically bonded to the wafer, wherein the calcining is performed at a temperature of from about 200° C. to about 800° C.; depositing a metal layer comprising Cu on the adhesion layer within the via; thermally processing the metal layer and the adhesion layer such that a portion of the MnOₓ of the adhesion layer changes oxidation state to bond to the metal layer comprising Cu; and reducing a portion of Cu in the metal layer comprising Cu under a reducing agent after the thermal processing of the metal layer comprising Cu and the adhesion layer.

These and other features, advantages, and objects of the present disclosure will be further understood and appreciated by those skilled in the art by reference to the following specification, claims, and appended drawings.

### BRIEF DESCRIPTION OF THE DRAWINGS

The following is a description of the figures in the accompanying drawings. The figures are not necessarily to scale, and certain features and certain views of the figures may be shown exaggerated in scale or in schematic in the interest of clarity and conciseness.

In the drawings:

FIG. 1 is a cross-sectional view of an article, according to at least one example;

FIG. 2 is a schematic flow diagram of a method of forming the article, according to at least one example;

FIG. 3 is an image of a Comparative Example;

FIG. 4A is an image of an electroless copper layer deposited on a layer of solution applied MnOₓ nanoparticles, according to a First Example of the present disclosure;

FIG. 4B is an image of a copper layer electroplated on the electroless copper layer after a thermal treatment, according to the First Example of the present disclosure;

FIG. 4C is an image of the deposited copper layer of FIG. 4B having passed a 3N/cm and 5N/cm tape test, according to the First Example of the present disclosure;

FIG. 4D is an image of a sample consistent with the First Example of the present disclosure having passed a crosshatched tape test;

FIG. 5A is an image of a copper layer deposited on a layer of sol-gel applied MnOₓ nanoparticles having passed a 3N/cm tape test, according to a Second Example of the present disclosure; and

FIG. 5B is an image of a copper layer deposited on a layer of sol-gel applied MnOₓ nanoparticles having passed a crosshatched tape test, according to the Second Example of the present disclosure.

### DETAILED DESCRIPTION

Additional features and advantages of the invention will be set forth in the detailed description which follows and will be apparent to those skilled in the art from the description, or recognized by practicing the invention as described in the following description, together with the claims and appended drawings.

As used herein, the term “and/or,” when used in a list of two or more items, means that any one of the listed items can be employed by itself, or any combination of two or more of the listed items can be employed. For example, if a composition is described as containing components A, B, and/or C, the composition can contain A alone; B alone; C alone; A and B in combination; A and C in combination; B and C in combination; or A, B, and C in combination.

In this document, relational terms, such as first and second, top and bottom, and the like, are used solely to distinguish one entity or action from another entity or action, without necessarily requiring or implying any actual such relationship or order between such entities or actions.

It will be understood by one having ordinary skill in the art that construction of the described disclosure, and other components, is not limited to any specific material. Other exemplary embodiments of the disclosure disclosed herein may be formed from a wide variety of materials, unless described otherwise herein.

For purposes of this disclosure, the term “coupled” (in all of its forms: couple, coupling, coupled, etc.) generally means the joining of two components (electrical or mechanical) directly or indirectly to one another. Such joining may be stationary in nature or movable in nature. Such joining may be achieved with the two components (electrical or mechanical) and any additional intermediate members being integrally formed as a single unitary body with one another or with the two components. Such joining may be permanent in nature, or may be removable or releasable in nature, unless otherwise stated.

As used herein, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. When the term “about” is used in describing a value or an end-point of a range, the disclosure should be understood to include the specific value or end-point referred to. Whether or not a numerical value or end-point of a range in the specification recites “about,” the numerical value or end-point of a range is intended to include two embodiments: one modified by “about,” and one not modified by “about.” It will be further understood that the end-points of each of the ranges are significant both in relation to the other end-point, and independently of the other end-point.

The terms “substantial,” “substantially,” and variations thereof as used herein are intended to note that a described feature is equal or approximately equal to a value or description. For example, a “substantially planar” surface is intended to denote a surface that is planar or approximately planar. Moreover, “substantially” is intended to denote that two values are equal or approximately equal. In some embodiments, “substantially” may denote values within about 10% of each other.

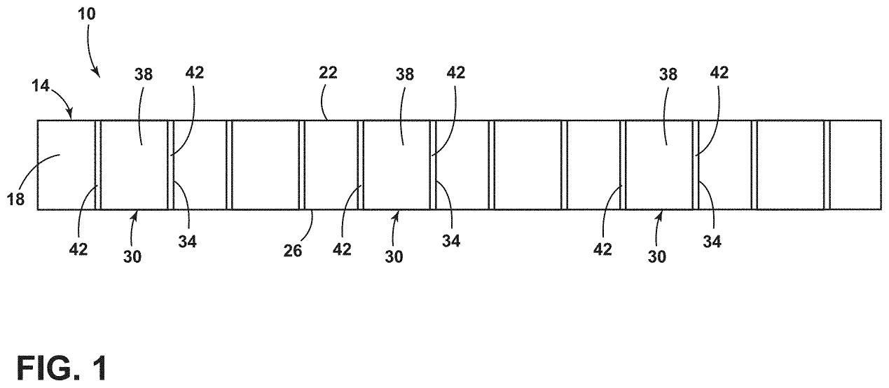

Referring now to FIG. 1, depicted is an article 10 including a wafer 14 having a body 18 which defines a first surface 22 and a second surface 26. The wafer 14 defines a via 30 having a sidewall surface 34 extending between the first and second surfaces 22, 26 through the body 18. A metallic component 38 is positioned within the via 30. The article 10 includes an adhesion layer 42 which adheres the metallic component 38 to the sidewall surface 34. As will be explained in greater detail below in connection with one embodiment, the adhesion layer 42 is chemically bonded to both the metallic component 38 and the sidewall surface 34 of the via 30. As used herein, the term “chemically bonded” encompasses covalent bonding, ionic bonding and metallic bonding between the features which are described as chemically bonded.

The wafer 14 has the body 18 which defines the first and second surfaces 22, 26. It will be understood that the wafer 14 and/or body 18 may further define one or more minor surfaces positioned along edges thereof. The wafer 14 may be a substantially planar sheet, although other examples of the article 10 may utilize a curved or otherwise shaped or sculpted wafer 14. Further, the wafer 14 may vary in thickness, width and/or length across the wafer 14 without departing from the teachings provided herein.

According to various examples, the wafer 14 may be composed of an electrically insulating material or a semiconducting material. For example, the wafer 14 may be composed of a glass material, a glass-ceramic material, a ceramic material, silicon-based semiconductor material and/or combinations thereof. Glass-based examples of the wafer 14 may include soda lime glass, float glass, fluoride glass, aluminosilicate glass, phosphate glass, borate glass, borosilicate glass, chalcogenide glass, aluminum oxide, silicon having an oxidized surface, alkali aluminosilicate glass, alkali containing borosilicate glass, alkali aluminoborosilicate glass and/or combinations thereof. In glass examples of the wafer 14, the wafer 14 may be strengthened or non-strengthened. For instance, glass examples of the wafer 14 may be strengthened by thermal tempering or by ion-exchange. Further, the wafer 14 may include a sapphire material. In ceramic examples of the wafer 14, the wafer 14 may be at least partially composed of alumina, beryllia, ceria, zirconia, barium-based ceramics (e.g., BaTiO₃) and/or combinations thereof. Further, ceramic examples of the wafer 14 may include non-oxide ceramics such as carbides, borides, nitrides and silicides.

The wafer 14 may be substantially translucent, clear, transparent and/or free from light scattering. For example, the wafer 14 may be optically transparent to light having a wavelength in the range of between about 100 nanometers and about 1,200 nanometers, or in a range of about 250 nanometers to about 1,100 nanometers. In some examples, the transmission of light through the wafer 14 may be dependent on the wavelength of the light. For example, the wafer 14 may be optically opaque or translucent over a visible wavelength band (e.g., from about 400 nm wavelength to about 700 nm wavelength) while substantially or fully transmissive at non-visible wavelengths or vice versa.

According to various examples, the wafer 14 can have a thickness (i.e., as measured from the first surface 22 to the second surface 26) ranging from about 50 μm to about 5 mm. Exemplary thicknesses of the wafer 14 range from about 1 μm to about 1000 μm, or from about 100 μm to about 1000 μm or from about 100 μm to about 500 μm. For example, the wafer 14 may have a thickness of about 1 μm, about 5 μm, about 10 μm, about 20 μm, about 30 μm, about 40 μm, about 50 μm, about 60 μm, about 70 μm, about 80 μm, about 90 μm, about 100 μm, about 200 μm, about 300 μm, about 400 μm, about 500 μm, about 600 μm, about 700 μm, about 800 μm, about 900 μm, about 1000 μm, about 2000 μm, about 3000 μm, about 4000 μm or about 5000 μm or any and all values and ranges therebetween. Additionally or alternatively, the thickness of the wafer 14 may vary along one or more of its dimensions for aesthetic and/or functional reasons. For example, the edges of the wafer 14 may be thicker as compared to more central regions of the wafer 14, or vice versa. The length, width and thickness dimensions of the wafer 14 may also vary according to the application or use of the article 10.

The body 18 of the wafer 14 defines or includes the vias 30. The wafer 14 may define a single via 30 or may define a plurality of vias 30. The vias 30 may be defined at predetermined locations around the wafer 14 and/or may be positioned randomly. For example, the vias 30 may form a pattern, indicia and/or text. According to various examples, the pattern of the vias 30 may correspond to an electrical circuit or chip. The vias 30 and/or the body 18 define the sidewall surfaces 34 which extend around the vias 30. The vias 30 may have an irregular, circular, oval, triangular, square, rectangular, or higher order polygon cross-sectional shape. It will be understood that the vias 30 may have different cross-sectional shapes than one another without departing from the teachings provided herein. As the vias 30 extend through the body 18 of the wafer 14, the vias 30 may have the same length as the thickness of the body 18. In other words, the vias 30 may have a length of about 1 μm, about 5 μm, about 10 μm, about 20 μm, about 30 μm, about 40 μm, about 50 μm, about 60 μm, about 70 μm, about 80 μm, about 90 μm, about 100 μm, about 200 μm, about 300 682 m, about 400 μm, about 500 μm, about 600 μm, about 700 μm, about 800 μm, about 900 μm, about 1000 μm, about 2000 μm, about 3000 μm, about 4000 μm or about 5000 μm. It will be understood that in examples where the thickness of the wafer 14 changes with position, the vias 30 may also change in length such that different vias 30 have different lengths.

The diameter, or longest length dimension in a cross-sectional plane, of the vias 30 may be from about 1 μm to about 300 μm, or from about 5 μm to about 200 μm, or from about 10 μm to about 100 μm. For example, the vias 30 may have a diameter of about 10 μm, about 20 μm, about 30 μm, about 40 μm, about 50 μm, about 60 μm, about 70 μm, about 80 μm, about 90 μm or about 99 μm. It will be understood that the diameter of the via 30 may vary across the length of the via 30. In other words, one or more of the vias 30 may be tapered. It will be understood that the vias 30 may have different diameters or different degrees of tapering than one another.

The vias 30 may have an aspect ratio (e.g., expressed as the proportional relationship between the length of the via 30 to the width of the via 30) of from about 1:1 to about 30:1, or from about 2:1 to about 20:1, or from about 3:1 to about 15:1. For example, the vias 30 may have an aspect ratio of about 1:1 or greater, about 2:1 or greater, about 3:1 or greater, about 4:1 or greater, about 5:1 or greater, about 6:1 or greater, about 7:1 or greater, about 8:1 or greater, about 9:1 or greater, about 10:1 or greater, about 11:1 or greater, about 12:1 or greater, about 13:1 or greater, about 14:1 or greater, about 15:1 or greater, about 16:1 or greater, about 17:1 or greater, about 18:1 or greater, about 19:1 or greater, about 20:1 or greater and all values therebetween. It will be understood that the aspect ratio of the vias 30 may be different from one another or the aspect ratio of the vias 30 may be the same.

According to various examples, one or more of the vias 30 may only partially extend into the body 18 of the wafer 14. In examples of the via 30 in which the via 30 only extends partly into the body 18 of the wafer 14, such a via 30 may be referred to as a “blind via.” In yet other examples, one or more of the vias 30 may extend from the first or second surfaces 22, 26 and exit one of the minor side surfaces of the wafer 14. In such examples, the via 30 may be known as a through via.

According to various examples, one or more of the vias 30 may be formed at an angle between the first and second surfaces 22, 26. In other words, a centerline axis of the vias 30 may not be orthogonal to the first and second surfaces 22, 26. In such examples, a centerline axis of the vias 30 may be at an angle of from about 0° to about 40° from an orthogonal axis of the first and second surfaces 22, 26. It will be understood that the angle of the vias 30 may be different from one another or may be the same.

The vias 30 may take a variety of cross-sectional shapes. For example, one or more of the vias 30 may be tapered from one end to another (e.g., a diameter of the vias 30 proximate the first surface 22 may be greater than the diameter of the via 30 proximate the second surface 26), hourglass-shaped (i.e., the via 30 may be tapered towards a minimum diameter located within the body 18 of the wafer 14), other shapes and/or combinations thereof.

The adhesion layer 42 may be positioned on the first surface 22, the sidewall surface 34 and/or the second surface 26. It will be understood that the adhesion layer 42 may be applied to one or more surfaces (e.g., first surface 22, the sidewall surface 34 and/or the second surface 26) and then later removed such that the adhesion layer 42 only exists on a single surface (e.g., the sidewall surface 34). According to various examples, the adhesion layer 42 may be applied to one or more exterior surfaces (e.g., the first surface 22, the second surface 26 and/or the minor surfaces) of the wafer 14. The adhesion layer 42 directly contacts the sidewall surface 34 and covers a portion or the entirety of the sidewall surface 34. In one embodiment, the adhesion layer directly contacts the sidewall surface 34 along the entirety of its length.

The adhesion layer 42 may have a thickness of from about 1 nm to about 500 nm, or from about 10 nm to about 500 nm, or from about 10 nm to about 450 nm, or from about 20 nm to about 400 nm, or from about 25 nm to about 300 nm, or from about 30 nm to about 200 nm or from about 40 nm to about 100 nm. For example, the adhesion layer 42 may have a thickness of about 5 nm, about 10 nm, about 20 nm, about 30 nm, about 40 nm, about 50 nm, about 60 nm, about 70 nm, about 80 nm, about 90 nm, about 100 nm, about 200 nm, about 300 nm, about 400 nm or about 500 nm and all ranges and values therebetween. According to various examples, the thickness of the adhesion layer 42 may vary across the length of the via 30 or across any of the surfaces (e.g., first surface 22, the sidewall surface 34 and/or the second surface 26) on which the adhesion layer 42 is positioned.

According to various examples, the adhesion layer 42 may include one or more transition metals capable of multiple different oxidation states. As used herein, the oxidation state refers to the degree of oxidation (i.e., loss of electrons relative to a neutral charge state) of an atom in a chemical compound. Oxidation state may be expressed in terms of chemical formulae and/or as positive integers. An atom having a positive oxidation state (e.g. Cu⁺, Cu²⁺) is said to be in an oxidized state. An atom having a zero oxidation state is said to be in a neutral or metallic state (e.g. Cu⁰). Exemplary transition metals in the adhesion layer 42 may include Mn, Ti, Cu, Cr, V, other transition metals and/or combinations thereof. The transition metal may exist within the adhesion layer 42 at one or more different oxidation states. As will be explained in greater detail below, the adhesion layer 42 is configured to chemically bond to both the wafer 14 and the metallic component 38. In such examples, the adhesion layer 42 may utilize one or more of the transition metals listed above to chemically bond with the material of the wafer 14 (e.g. glass and/or ceramic) while also chemically bonding (e.g., metallically or covalently) with the metallic component 38. The ability of the transition metal within the adhesion layer 42 to chemically bond to both the material of the wafer 14 and the metallic component 38 is a function of the ability of the transition metal to change oxidation states based on processing as described in greater detail below. The ability of the adhesion layer 42 to chemically bond with both the wafer 14 and the metallic component 38 may be advantageous in securing the metallic component 38 within the via 30 of the wafer 14 through more than just mechanical interlocking, mechanical adhesion, or van der Waals association.

According to various examples, the adhesion layer 42 includes MnOₓ. As used herein MnOₓ represents oxides of Mn and may include Mn in one or more oxidation states. Oxides and oxidation states of Mn include MnO (Mn²⁺), Mn₂O₃ (Mn³⁺) MnO₂ (Mn⁴⁺) Mn₃O₄ (Mn⁴⁺), and Mn₂O₇ (Mn⁷⁺). As will be explained in greater detail below, the Mn present within the adhesion layer 42 may exist in a number of different oxidation states throughout the adhesion layer 42. For example, the portion of MnOₓ proximate or in direct contact with the sidewall surface 34 may have a higher oxidation state, or be more oxygen negative, such that the Mn tends to covalently bond with O atoms present in the wafer 14. Further, the portion of MnOₓ proximate or in contact with the metallic component 38 may have a lower oxidation state, or be less oxygen negative, such that the Mn tends to form metallic bonds with metal atoms present in the metallic component 38.

It will be understood that the adhesion layer 42 may include one or more other materials (e.g., binders, additives, etc.) without departing from the teachings provided herein. For example, the adhesion layer 42 may include one or more materials used in the formation or deposition of the adhesion layer 42.

As explained above, the metallic component 38 is positioned within the via 30 of the wafer 14. The metallic component 38 may extend a portion, a majority, substantially all or all of an axial length of the via 30. The metallic component 38 may fill a portion, a majority, substantially all or all of a volume of the via 30.

The metallic component 38 may be composed of a pure metal or a metal alloy. The metallic component 38 may include Cu, Ag, Ni, Au, Pt, Pb, Cd, Cr, Rh, Sn, Zn, Sb, Ti, In and/or combinations thereof. In such an example, the metallic component 38 may include any one of Cu, Ag, Ni, Au, Pt, Pb, Cd, Cr, Rh, Sn, Zn, Sb, Ti and/or In in an amount of about 10 mol % or greater, or about 15 mol % or greater, or about 20 mol % or greater, or about 25 mol % or greater, or about 30 mol % or greater, or about 35 mol % or greater, or about 40 mol % or greater, or about 45 mol % or greater, or about 50 mol % or greater, or about 55 mol % or greater, or about 60 mol % or greater, or about 65 mol % or greater, or about 70 mol % or greater, or about 75 mol % or greater, or about 80 mol % or greater, or about 85 mol % or greater, or about 90 mol % or greater, or about 95 mol % or greater or any and all values and ranges between the given values. Further, the metallic component 38 may include any one of Cu, Ag, Ni, Au, Pt, Pb, Cd, Cr, Rh, Sn, Zn, Sb, Ti and/or In in an amount of about 95 mol % or less, or about 90 mol % or less, or about 85 mol % or less, 80 mol % or less, 75 mol % or less, 70 mol % or less, 65 mol % or less, 60 mol % or less, 55 mol % or less, 50 mol % or less, or about 45 mol % or less, or about 40 mol % or less, or about 35 mol % or less, or about 30 mol % or less, or about 25 mol % or less, or about 20 mol % or less, or about 15 mol % or less, or about 10 mol % or less, or about 9 mol % or less, or about 8 mol % or less, or about 7 mol % or less, or about 6 mol % or less, or about 5 mol % or less, or about 4 mol % or less, or about 3 mol % or less, or about 2 mol % or less, or about 1 mol % or less or any and all values and ranges therebetween.

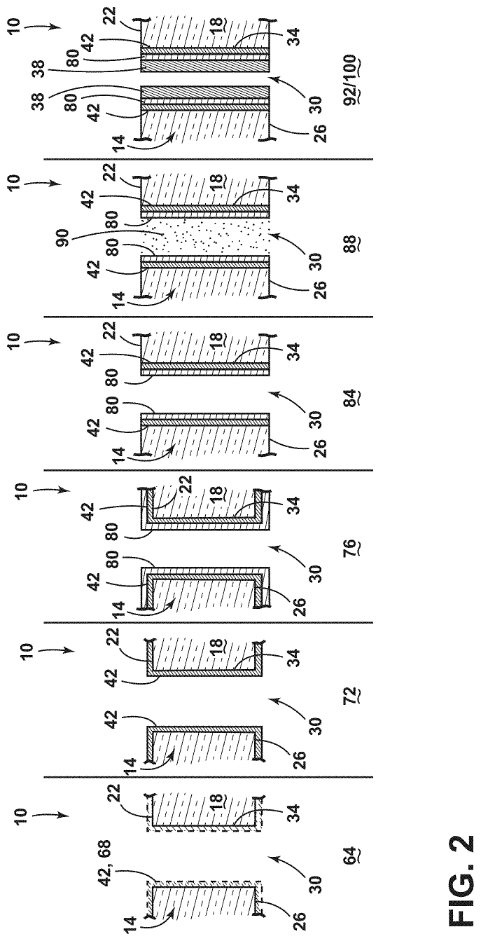

Referring now to FIG. 2, depicted is a method of forming the article 10. The method 60 may begin with a step 64 of forming the adhesion layer 42 including a transition metal oxide on the wafer 14. As explained below, the adhesion layer 42 may be applied to the wafer 14 as a mixture 68. It will be understood that prior to the start of the method 60, glass-containing examples of the wafer 14 can be cleaned by immersion into, or an application of, a mixture of 30 wt % NH₄OH, 30 wt % H₂O₂, and water for 30 minutes followed by immersion into a mixture of 35 wt % HCl, 30 wt % H₂O₂, and water for 30 min. Following the cleaning, the wafer 14 may be rinsed with deionized water. Additionally or alternatively, the wafer 14 may be cleaned with one or more plasma-assisted processes.

In a first example of step 64, the mixture 68 may be a solution. In such an example, the adhesion layer 42 may be formed by applying a solution to the surfaces of the wafer 14. The solution may include a transition metal suspended in a solvent which is applied to the wafer 14. It will be understood that the transition metal may be an oxide form or metallic form. A transition metal oxide is preferred. In solution examples of the mixture 68, the solution including the transition metal may be applied to the wafer 14, the body 18, the first surface 22, the second surface 26 and/or the sidewall surface 34 of the via 30 through a variety of methods. For example, the solution may be applied to the wafer 14 through dip coating (i.e., the wafer 14 may be partially or fully submerged within the solution), spray coating (i.e., the solution may be sprayed on one or more of the surfaces of the wafer 14), spin coating (e.g., where the wafer 14 may be spun at a rate of from about 800 RPM to about 1200 RPM while the solution is applied) and/or combinations thereof.

The transition metal within the mixture 68 may be composed of a plurality of particles in a solution. Solutions include a plurality of particles in one or more liquids. Liquids include solvents, suspension media, and combinations thereof. According to various examples, the transition metal may be composed of nanoparticles, preferably transition metal oxide nanoparticles. The transition metal may be composed of nanoparticles having a D50 largest length dimension of about 5 nm, or about 10 nm, or about 20 nm, or about 25 nm, or about 30 nm, or about 40 nm, or about 50 nm, or about 60 nm, or about 70 nm, or about 80 nm, or about 90 nm, or about 100 nm, or about 200 nm, or about 300 nm, or about 400 nm, or about 500 nm or any and all values and ranges between the given values. For example, the transition metal may be composed of nanoparticles having a D50 largest length dimension of from about 5 nm to about 500 nm, or from about 10 nm to about 500 nm, or from about 5 nm to about 400 nm, or from about 5 nm to about 300 nm, or from about 50 nm to about 200 nm, or from about 5 nm to about 100 nm, or from about 5 nm to about 90 nm, or from about 5 nm to about 80 nm, or from about 5 nm to about 70 nm, or from about 5 nm to about 60 nm, or from about 5 nm to about 50 nm, or from about 5 nm to about 40 nm, or from about 5 nm to about 30 nm, or from about 5 nm to about 20 nm.

The transition metal may have a weight percent (wt %) in the mixture 68 of from about 0.1 wt % to about 10.0 wt %, or from about 0.1 wt % to about 1.0 wt %, or from about 0.1 wt % to about 0.9 wt %, or from about 0.1 wt % to about 0.8 wt %, or from about 0.1 wt % to about 0.7 wt %, or from about 0.1 wt % to about 0.6 wt %, or from about 0.1 wt % to about 0.5 wt %, or from about 0.1 wt % to about 0.4 wt %, or from about 0.1 wt % to about 0.3 wt %, or from about 0.1 wt % to about 0.2 wt %. For example, the weight percent of the of the transition metal within the mixture 68 may be about 0.1 wt %, or about 0.2 wt %, or about 0.3 wt %, or about 0.4 wt %, or about 0.5 wt %, or about 0.6 wt %, or about 0.7 wt %, or about 0.8 wt %, or about 0.9 wt %, or about 1.0 wt %, or about 2.0 wt %, or about 10 wt % or any and all values and ranges between the given values.

The solution may include a single liquid or a combination of liquids. For example, the solution may include ethanol, acetic acid, toluene, methanol, isopropanol, hexane, dimethylformamide, tetrahydrofuran, acetone, water, polar liquids, non-polar liquids, other liquids and/or combinations thereof. In combination examples, one liquid may have a volume to volume ratio to another liquid of about 40:1, or about 20:1, or about 15:1 or about 10:1, or about 5:1, or about 1:1 or any and all values therebetween. For example, the solution may be a mixture of ethanol and acetic acid at a volume to volume ratio of about 20:1.

The solution may optionally include one or more polymeric binders. Polymeric binders include poly(ethylene oxide), polyethylene glycol, poly(diallyldimethylammonium, polyethylene, polypropylene, ethylene phenylacetate, polyvinylpyrrolidone, polyvinylidene difluoride, polyvinylidene fluoride, other polymeric binders and/or combinations thereof. The polymeric binder may have a weight percent in the solution of from about 0.1 wt % to about 2.0 wt %, or from about 0.1 wt % to about 1.0 wt %, or from about 0.1 wt % to about 0.9 wt %, or from about 0.1 wt % to about 0.8 wt %, or from about 0.1 wt % to about 0.7 wt %, or from about 0.1 wt % to about 0.6 wt %, or from about 0.1 wt % to about 0.5 wt %, or from about 0.1 wt % to about 0.4 wt %, or from about 0.1 wt % to about 0.3 wt %, or from about 0.1 wt % to about 0.2 wt %. For example, the weight percent of the of the polymeric binder within the solution may be about 0.1 wt %, or about 0.2 wt %, or about 0.3 wt %, or about 0.4 wt %, or about 0.5 wt %, or about 0.6 wt %, or about 0.7 wt %, or about 0.8 wt %, or about 0.9 wt %, or about 1.0 wt %, or about 2.0 wt % or any and all values and ranges between the given values.

After application of the solution to the wafer 14, the wafer 14 may be dried such that the liquid is removed and the adhesion layer 42 is formed on the surfaces of the wafer 14. It will be understood that later steps involving thermal processing may aid in the removal of the liquid and therefore the formation of the adhesion layer 42 without departing from the teachings provided herein.

In a second example of step 64, the mixture 68 is a solution that contains a transition metal compound. In one embodiment, the transition metal compound is a salt. In another embodiment, the transition metal compound that contains a transition metal and oxygen. In a further embodiment, the transition metal compound includes a transition metal directly bonded to oxygen. In one embodiment, the adhesion layer 42 may be formed on a surface of the wafer 14 from the solution through reaction of the compound in a sol-gel process The solution may include any of the above-noted liquids or combinations thereof. According to various examples, the transition metal compound may be a salt. For example, the transition metal compound may be a carbonate, sulfate, nitrate, cyanide and/or chloride. Other transition metal compounds include acetates alkoxides, acetylacetonates, chelates, hydroxides, and sol-gel precursors. The solution may include one or more stabilizers (e.g., a pH modifier configured to control a pH of the solution) to stabilize the solution containing a transition metal compound. Once the solution is formed, a pH modifier may be added to the solution to increase or decrease the pH of the solution. Shifting of the pH of the solution from acidic to neutral or basic may promote gelling, or an increase of viscosity of the solution. The pH modifier may include basic hydroxides such as ammonium hydroxide, potassium hydroxide, sodium hydroxide or other pH modifiers and/or combinations thereof. In other embodiments, the pH modifier may include an acid such as hydrochloric acid, sulfuric acid, nitric acid, phosphoric acid, acetic acid, citric acid. Once the pH modifier is added to the solution, the solution may be applied to the wafer 14 (e.g., through dip coating, spray coating, spin coating and/or combinations thereof). Gelling of the solution may be carried out at a temperature of from about 0° C. to about 100° C. for a time period of from about 5 minutes to about 1.5 hours. The wafer 14, having the gelled solution, may then be permitted to dry to form the adhesion layer 42. As with the first example of step 64, it will be understood that later steps involving thermal processing may aid in the removal of the liquid present in the solution and therefore the formation of the adhesion layer 42 without departing from the teachings provided herein.

Once the adhesion layer 42 has been formed on the wafer 14, a step 72 of calcining the adhesion layer 42 is performed to induce formation of a chemical bond between the adhesion layer 42 and the wafer 14. Calcining of the adhesion layer 42 to form a calcined adhesion layer may be performed at a temperature of about 200° C., or about 250° C., or about 300° C., or about 350° C., or about 400° C., or about 450° C., or about 500° C., or about 550° C., or about 600° C., or about 650° C., or about 700° C., or about 750° C., or about 800° C., or about 850° C., or about 900° C., or about 950° C., or about 1000° C. or any and all values and ranges between any of the given values. For example, the calcining may take place at a temperature of from about 200° C. to about 1000° C., or from about 200° C. to about 900° C., or from about 200° C. to about 800° C., or from about 200° C. to about 700° C., or from about 200° C. to about 600° C., or from about 200° C. to about 500° C., or from about 300° C. to about 500° C.

The adhesion layer 42 may be calcined for a time period of about 0.5 hours, or about 1 hour, or about 1.5 hours, or about 2 hours, or about 2.5 hours, or about 3 hours, or about 3.5 hours or any and all values and ranges of time therebetween. For example, the adhesion layer 42 may be calcined for a time period of from about 1 hour to about 3 hours or for a time period of from about 1 hour to about 2 hours. The adhesion layer 42 may be calcined in air or in an inert atmosphere (e.g., N₂, noble gases, etc.). Further, the adhesion layer 42 may be calcined under a pressure of from about 0.75 atm to about 1.25 atm.

Calcining of the adhesion layer 42 may induce a change in the oxidation state of the transition metal of the adhesion layer 42. A change in oxidation state may facilitate formation of a chemical bond between the adhesion layer 42 and the wafer 14 when forming the calcined adhesion layer. For example, a portion of the MnOₓ present in the adhesion layer 42 proximate the sidewall surface 34 of the via 30 of the wafer 14 may transition to a higher oxidation state (e.g., from Mn⁺ and/or Mn²⁺ to Mn³⁺ and/or Mn⁴⁺ ) which may allow the Mn present in the adhesion layer 42 to bond with 0 atoms present in the composition of the wafer 14 thereby chemically bonding (i.e., covalently) the adhesion layer 42 to the wafer 14. As explained above, Mn, Ti, Cu, Cr and V all exhibit multiple oxidation states which may be utilized to bond the adhesion layer 42 to the wafer 14. The chemical bond between the adhesion layer 42 and the wafer 14 may include a chemical linkage of the type TM-O-M, where TM is a transition metal from the adhesion layer 42 and M is an element of wafer 14 (e.g. a metal or Si).

Conventional adhesion films often utilize Zn as it has a single oxidation state which is roughly halfway between the oxygen negativity useful for glass adhesion and the oxygen negativity usefully for metallic bonding. As Zn has only one oxidation state, bonding to both the glass and the metal may equally suffer resulting in delamination by Zn-based adhesion films from wafers having an oxide composition. Use of the presently disclosed adhesion layer 42 including the transition metal, and specifically Mn, may be particularly advantageous as Mn exhibits the largest change in enthalpy of oxidation (ΔH) between its highest and lowest oxidation states. Such a large change of enthalpy of oxidation between the highest and lowest oxidation states of Mn is advantageous in providing chemical bonds to dissimilar materials (e.g., metal and glass). In one embodiment, the calcined adhesion layer includes a transition metal in two or more oxidation states (e.g. two or more of Mn⁺, Mn²⁺, Mn³⁺, or Mn⁴⁺).

Once the adhesion layer 42 has been calcined, a step 76 of depositing a conductive layer 80 on the adhesion layer 42 is performed. According to various examples, the conductive layer 80 is a layer that includes one or more metals. A preferred metal is Cu and conductive layer 80 is preferentially deposited on at least a portion of the calcined adhesion layer present within the via 30. In one embodiment, the conductive layer 80 is deposited to cover the entirety of the calcined adhesion layer in the via 30. It will be understood that the conductive layer 80 may include any of the metals noted above in connection with the metallic component 38 without departing from the teachings provided herein. Further, the conductive layer 80 may be formed on the wafer 14 exterior to the via 30 (i.e., the first and/or second surfaces 22, 26) and optionally later removed. The conductive layer 80 may have a thickness of 50 nm, or about 100 nm, or about 150 nm, or about 200 nm, or about 300 nm, or about 400 nm, or about 500 nm, or about 600 nm, or about 700 nm, or about 800 nm, or about 900 nm, or about 1 μm, or about 5 μm, or about 10 μm, or about 20 μm, or about 30 μm, or about 40 μm, or about 50 μm or any and all values and ranges therebetween. For example, the conductive layer 80 may have a thickness of from about 50 nm to about 50 μm, or from about 50 nm to about 10 μm, or from about 50 nm to about 1 μm, or from about 50 nm to about 500 nm, or from about 50 nm to about 100 nm.

According to various examples, the conductive layer 80 may be formed by electroless plating of a metal layer on the calcined adhesion layer. During electroless deposition of the metal layer, a catalyst may be applied to the calcined adhesion layer to promote nucleation and/or growth of the metal layer. The catalyst may include K₂PdCl₄, ionic palladium or Sn/Pd colloidal solutions. If K₂PdCl₄ or ionic palladium chemistries are used, reduction of the palladium complex into metallic palladium, in the form of colloids may be performed. A solution containing oxidized states of the metal of the metal layer (e.g., Cu⁻ or Cu²⁺) is then introduced to the catalyzed surface of the calcined adhesion layer. A chemical reaction (e.g., 2HCHO+4OH → H₂ (gas)+H₂O₂+⁻2e⁻) is carried out to produce electrons which are used in the reduction of the oxidized state(s) of the metal of the metal layer to produce a metal layer with the metal in a neutral state (e.g. Cu⁰). Reduction of the oxidized metal to a neutral state causes the metal to collect on the calcined adhesion layer and grow from the catalyzed surface to form a metal layer as an embodiment of conductive layer 80.

Once the conductive layer 80 is formed on the calcined adhesion layer, a step 84 of thermally processing the conductive layer 80 and the calcined adhesion layer to induce formation of a chemical bond between the calcined adhesion layer and the conductive layer 80. In one embodiment, the conductive layer 80 comprises a metal layer and the thermal processing induces formation of a chemical bond between the calcined adhesion layer and the metal layer. In some embodiments, thermal processing causes a portion of a transition metal of the calcined adhesion layer to change oxidation state during formation of a chemical bond between the calcined adhesion layer and the metal layer. In other words, in one embodiment, step 84 may include heating the conductive layer 80 and the calcined adhesion layer such that a portion of the Mn in the MnOₓ of the calcined adhesion layer changes oxidation state to chemically bond to the conductive layer 80. In an embodiment in which conductive layer 80 is a metal layer and the calcined adhesion layer includes MnOₓ for example, formation of a chemical bond between the calcined adhesion layer and the metal layer in step 84 may include a change in the oxidation state of a portion of the Mn in the MnOₓ.

As highlighted in connection with step 84, the thermal processing of the calcined adhesion layer may allow a transition metal present within the calcined adhesion layer to change oxidation states. In one embodiment, a portion of the transition metal of the calcined adhesion layer in close proximity to a conductive layer 80 comprising a metal may change oxidation state in step 84. For example, a portion of the MnOₓ present in a portion of the calcined adhesion layer in close proximity to conductive layer 80 may include Mn in a higher oxidation state (e.g., Mn₂O₃ or Mn₃O₄) and this portion of the MnOₓ may undergo reduction in step 84 to form MnOₓ with Mn in a lower oxidation state (e.g., MnO or MnO₂) during formation of a chemical bond between the calcined adhesion layer and conductive layer 80. In one embodiment, a portion of the MnOₓ present in the calcined adhesion layer is reduced to lower the oxidation state of Mn during thermal processing in step 84 to form a chemical bond between the calcined adhesion layer and a metal layer as an embodiment of conductive layer 80. The calcined adhesion layer is further chemically bonded to the wafer 14. In one embodiment, the calcined adhesion layer is a transition metal oxide that includes a transition metal in two or more oxidation states. In one embodiment, the calcined adhesion layer includes MnOₓ where Mn is in two or more oxidation states. The Mn in the portion of the MnOₓ that is chemically bonded to or in close proximity to the conductive layer 80 may differ in oxidation state from the Mn in the portion of the MnOₓ that is chemically bonded to or in close proximity to the wafer 14. In one embodiment, the Mn in the MnOₓ adjacent to the wafer has a higher oxidation state than the Mn in the MnOₓ adjacent to the conductive layer 80 (or a metal layer as an embodiment of conductive layer 80) It will be understood that the first and/or second surfaces 22, 26 of the wafer 14 may be polished or otherwise cleaned such that the adhesion layer 42, calcined adhesion layer, and/or conductive layer 80 present on the first and/or second surfaces 22, 26 are removed.

In one embodiment, thermal processing of the conductive layer 80 and the calcined adhesion layer in step 84 leads to formation of an intermix layer at the interface of the conductive layer 80 and calcined adhesion layer. The intermix layer includes an oxidized portion of the conductive layer 80 intermixed with a portion of the calcined adhesion layer. In one embodiment, the conductive layer 80 comprises a metal and the intermix layer includes the metal in an oxidized state. In one embodiment, the conductive layer 80 includes Cu in a neutral state (Cu⁰) and thermal processing in step 84 forms an intermix layer in which a portion of the neutral Cu is oxidized to Cu⁺ and/or Cu²⁺. The oxidized Cu is interspersed with a portion of the transition metal oxide in the calcined adhesion layer in the intermix layer. While not wishing to be bound by theory, it is postulated that oxidation of a metal in conductive layer 80 facilitates formation of a chemical bond between the calcined adhesion layer and the conductive layer 80. In one embodiment, the oxidized portion of the metal from the conductive layer 80 in the intermix layer chemically bonds to a transition metal oxide in the intermix layer.

In one embodiment, chemical bonding extends from the wafer 14 to the calcined adhesion layer and from the calcined adhesion layer to the intermix layer. In another embodiment, a portion of conductive layer 80 remains outside of the intermix layer and includes a metal in a neutral state, and the chemical bonding further extends from the intermix layer to the conductive layer 80. As used herein, a portion of conductive layer 80 outside of the intermix layer is a portion exclusive of intermixing with a transition metal oxide from the calcined adhesion layer. The extensive chemical bonding achievable from an adhesion layer 42 comprising MnOₓ leads to stronger adhesion of metallic component 38 in via 30 of wafer 14. In one embodiment, Mn in the portion of MnOₓ of the calcined adhesion layer in the intermix layer has a lower oxidation state than Mn in the portion of MnOₓ of the calcined adhesion layer outside of the intermix layer. The diversity of oxidation states of Mn is believed to be advantageous in achieving the extended chemical bonding that improves adhesion. Higher oxidation states of Mn are believed to promote chemical bonding between the calcined adhesion layer and the wafer 14, while the lower oxidation states of Mn are believed to promote chemical bonding between the calcined adhesion layer and the conductive layer 80 (and ultimately metallic component 38 via the intermix layer). It is believed that adhesion is promoted through calcining and/or thermal processing that provides conditions that establish a gradient or non-uniform distribution of oxidation states of Mn in MnOₓ. Higher oxidation states of Mn are preferred in the portion of MnOₓ of the calcined adhesion layer adjacent to the wafer 14 and lower oxidation states of Mn are preferred in the portion of MnOₓ of the calcined adhesion layer adjacent to conductive layer 80.

Thermal processing of the calcined adhesion layer and the conductive layer 80 in step 84 may be performed at a temperature of about 200° C., or about 250° C., or about 300° C., or about 350° C., or about 400° C., or about 450° C., or about 500° C., or about 550° C., or about 600° C., or about 650° C., or about 700° C., or about 750° C., or about 800° C. or any and all values and ranges between any of the given values. For example, the thermal processing may take place at a temperature of from about 200° C. to about 800° C., or from about 200° C. to about 700° C., or from about 200° C. to about 600° C., or from about 200° C. to about 500° C., or from about 300° C. to about 500° C. In one embodiment, the thermal processing occurs in air.

The thermal processing of step 84 may be carried out for a time period of about 1 minute, or about 2 minutes, or about 3 minutes, or about 4 minutes, or about 5 minutes, or about 6 minutes, or about 7 minutes, or about 8 minutes, or about 9 minutes, or about 10 minutes, or about 11 minutes, or about 12 minutes, or about 13 minutes, or about 14 minutes, or about 15 minutes, or about 16 minutes, or about 17 minutes, or about 18 minutes, or about 19 minutes, or about 20 minutes, or about 60 minutes, or about 90 minutes, or about 120 minutes, or about 150 minutes, or about 180 minutes or any and all values and ranges therebetween. According to various examples, the thermal processing may be carried out in a furnace. In such an example, the furnace may be slowly ramped up to temperature with the wafer 14, adhesion layer 42 and metal layer 80 in the furnace at a rate of about 0.1° C. per minute, or about 0.5° C. per minute, or about 1.0° C. per minute, or about 1.5° C. per minute, or about 2.0° C. per minute. For example, heating of the conductive layer 80 and the calcined adhesion layer may be accomplished by ramping the temperature of the conductive layer 80 and the calcined adhesion layer from about 0.1° C. per minute to about 2.0° C. per minute. Further, the furnace may be ramped down at a rate of from about 0.1° C. per minute to about 2.0° C. per minute.

Next, a step 88 of reducing a portion of the conductive layer 80 with a reducing agent 90 may be performed. It will be understood that although described as separate steps, the reducing of the conductive layer 80 with the reducing agent 90 may be carried out during or after thermal processing of the conductive layer 80 and calcined adhesion layer in step 84 is taking place. The reducing agent 90 may be a gas, liquid or other substance configured to reduce the oxidation state of the conductive layer 80. For example, the reducing agent 90 may include H₂, metals, formic acid, sulfite compounds, other reducing agents and/or combinations thereof. Reduction of the conductive layer 80 includes reducing the oxidation state of oxidized forms of a metal in conductive layer 80 or the intermix layer to form metal in a neutral oxidation state. In one embodiment, reduction is not complete and a portion of metal remains in an oxidized state. For example, a portion of metal from conductive layer 80 in the intermix layer may remain in an oxidized state at conclusion of reducing step 88. Metal from conductive layer 80 may thus exist in two or more oxidation states in the intermix layer and/or portion of conductive layer 80 outside of the intermix layer.

Step 88 of reducing the portion of the conductive layer 80 may be performed in the presence of a reducing agent at a temperature of about 50° C., or about 100° C., or about 150° C., or about 200° C., or about 250° C., or about 300° C., or about 350° C., or about 400° C., or about 500° C., or about 600° C. or any and all values and ranges between any of the given values. For example, the reduction may take place at a temperature of from about 50° C. to about 600° C., or from about 200° C. to about 300° C.

Step 88 of the reduction of the conductive layer 80 in the presence of a reducing agent may be carried out for a time period of about 10 minutes, or about 15 minutes, or about 20 minutes, or about 25 minutes, or about 30 minutes, or about 35 minutes, or about 40 minutes, or about 45 minutes, or about 50 minutes, or about 55 minutes, or about 60 minutes or any and all values and ranges therebetween.

Step 88 of reducing a portion of the conductive layer 80 may be advantageous in providing a metallic and conductive surface on which to perform a step 92 of depositing the metallic component 38 on the reduced form of conductive layer 80. According to various examples, the depositing the metallic component 38 on the reduced conductive layer may be accomplished through electroplating the metallic component 38 on the reduced conductive layer. In electroplating examples, an electrolyte containing metal ions to be deposited as the metallic component 38 is introduced to the reduced conductive layer in the vias 30 followed by an electrochemical reduction of the ions to metal particles on the reduced conductive layer by applying current and/or voltage. Electrochemical deposition is continued until the metallic component 38 reaches a desired thickness. It will be understood that in examples where the metal of a metal layer as an embodiment of conductive layer 80 and the metal of the metallic component 38 are the same, the deposition of the metallic component 38 may result in the integration of the metal layer of conductive layer 80 and the metallic component 38 such that a distinguishable boundary between the metal layer of conductive layer 80 and the metallic component 38 is not discernible.

The metallic component 38 may be deposited until the metallic component 38 fills a diameter or width of the via 30 or to a desired thickness (i.e., as measured from the interface between the conductive layer 80 and a surface of the metallic component 38 within the via 30). The metallic component 38 may have a thickness of about 0.5 μm, or about 1 μm, or about 5 μm, or about 10 μm, or about 25 μm, or about 50 μm, or about 75 μm, or about 100 μm, or about 150 μm, or about 200 μm or any and all values and ranges between the given values. For example, the metallic component 38 may have a thickness of from about 0.5 μm to about 100 μm, or from about 0.5 μm to about 10 μm, or from about 0.5 μm to about 1 μm. It will be understood that the metallic component 38 may not entirely fill a cross-sectional width of the via 30 such that the metallic component 38 only extends around a perimeter of the via 30.

Once the metallic component 38 is formed, a step 100 of annealing the metallic component 38 may be performed. Annealing the metallic component 38 may be performed at a temperature of about 200° C., or about 250° C., or about 300° C., or about 350° C., or about 400° C., or about 450° C., or about 500° C., or about 550° C., or about 600° C., or about 650° C., or about 700° C., or about 750° C., or about 800° C. or any and all values and ranges between any of the given values. For example, annealing the metallic component 38 may take place at a temperature of from about 200° C. to about 800° C., or from about 200° C. to about 700° C., or from about 200° C. to about 600° C., or from about 200° C. to about 500° C., or from about 300° C. to about 500° C. Annealing the metallic component 38 may be advantageous in relieving residual stresses present within the metallic component 38. The annealing of the metallic component 38 may be performed in an inert atmosphere, under vacuum or under low-pressure conditions to prevent oxidation of the metallic component 38.

Use of the present disclosure may offer a variety of advantages. First, the adhesion layer 42 may be applied to the sidewall surface 34 of the wafer 14 through a solution or sol-gel based process. Conventional methods of forming adhesion layers in through-hole connections often rely on various sputtering techniques to form the adhesion layers which may be technically challenging and cost prohibitive. Further, high aspect ratio through holes may be non-uniformly coated with the adhesion layer due to the inability to deposit the adhesion layer deep within the through hole when using sputtering or other line-of-sight deposition techniques. Use of the presently disclosed techniques for depositing the adhesion layer 42 offers a solution based or sol-gel based process which may allow for easy and substantially uniform coating and formation of the adhesion layer 42, including in vias with high aspect ratios as described herein, which may result in a manufacturing time and cost savings. Further, as the solution or sol-gel may be deposited into high aspect ratio vias 30, a uniform adhesion layer 42 may be applied on the sidewall surface 34.

Second, use of the adhesion layer 42 which utilizes transition metals which may shift through multiple oxidation states allows the adhesion layer 42 to chemically bond to both the metallic component 38 and the sidewall surface 34. Conventional adhesion layers often utilize a material which is adept at bonding to one type of material (e.g., glass or metal), but not necessarily another material. In yet other examples, the material of the adhesion layer may have equal, but unsatisfactory, bonding to multiple types of material. Such a feature of the adhesion layer may be because the material of the adhesion layer is capable of only one or two oxidation states. Use of the presently disclosed adhesion layer 42 using Mn allows for the MnOₓ proximate the sidewall surface 34 to be transitioned to an oxidation state which tends to chemically bond with glass (i.e., covalently) of the sidewall surface 34 while a portion of the MnOₓ of the adhesion layer 42 proximate the metallic component 38 is shifted to an oxidation state which tends to bond to the metal (i.e., metallic bonding) of the metallic component 38.

### EXAMPLES

Provided below are both comparative examples and examples consistent with the present disclosure.

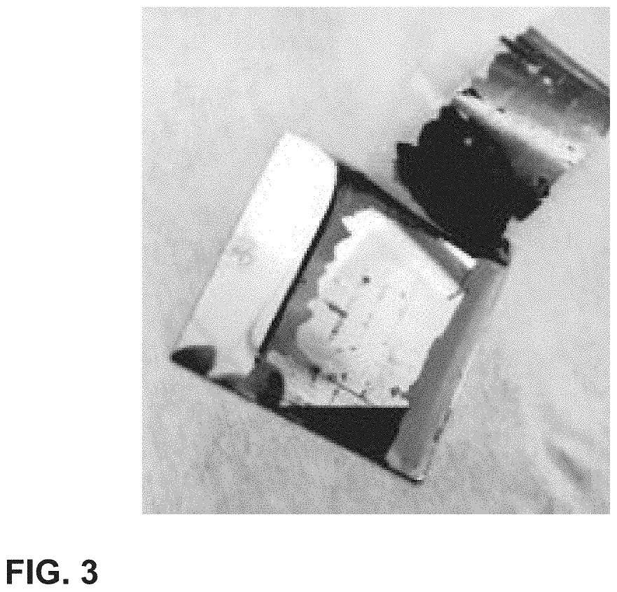

Referring now to FIG. 3, depicted is a Comparative Example to the present disclosure. The Comparative Example included a glass substrate on which electroless Cu layer and an electroplated Cu layer are formed. The glass of the Comparative Example was composed of an alkaline earth boro-aluminosilicate glass sold under the tradename Eagle® from Corning Incorporated®. The electroless Cu layer was formed by the deposition of a Pd catalyst on the glass substrate followed by activation and reduction of the Pd catalyst and the electroless plating of the electroless Cu layer. The thickness of the electroless Cu layer was between from about 100 nm to about 150 nm. The electroplated Cu layer was then electroplated onto the electroless Cu layer using a 1M CuSO₄ bath resulting in a 2.5 μm electroplated Cu layer. The electroplated Cu layer was annealed after formation. The Comparative Example was then subjected to a 3 N/cm tape test. The 3 N/cm tape test was performed consistent with ASTM D3359-09, without cross-hatching, where a pressure-sensitive tape is applied to the electroplated Cu layer and then removed. The electroplated Cu layer was removed from the sample indicating that sufficient adhesion between the glass substrate and the electroplated Cu layer did not exist to withstand the pulling force of the tape being removed. As such, the Comparative Example failed the 3 N/cm tape test. The failure of the Comparative Example is believed to have occurred due to the different types of bonding in the glass (i.e., covalent bonding) and the electroless Cu layer (i.e., metallic bonding) which resulted in only mechanical bonding between the glass substrate and the electroless Cu layer.

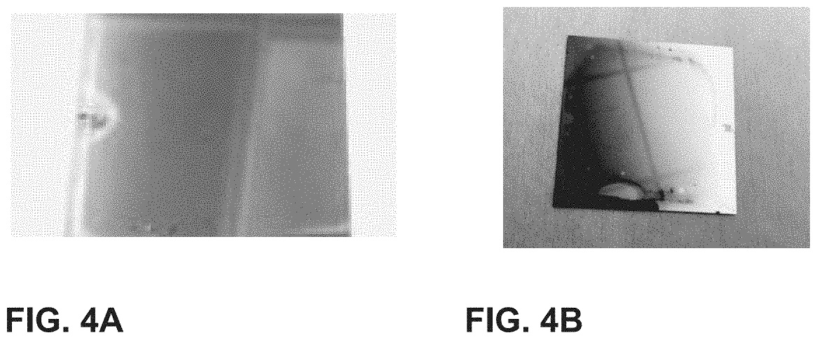

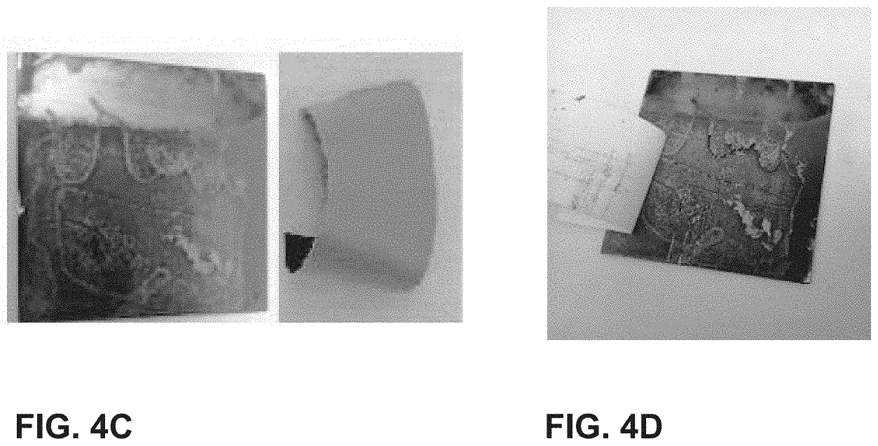

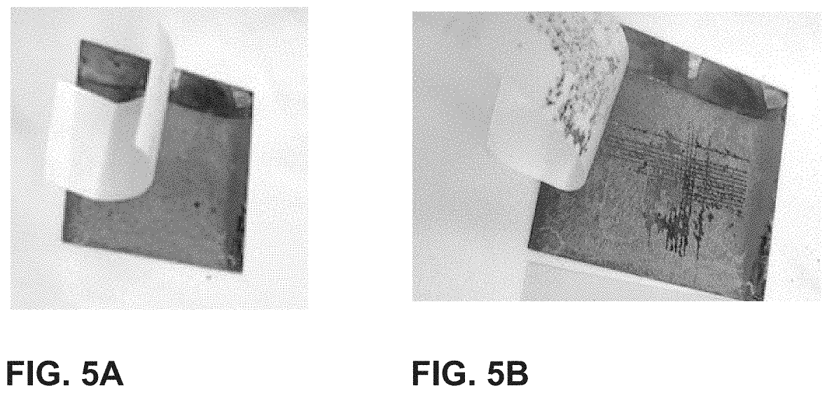

Referring now to FIGS. 4A-4D, provided is a First Example consistent with the present disclosure. FIG. 5A depicts a sample (e.g., the article 10) on which a solution of 0.4 wt % to about 0.66 wt % of MnOₓ nanoparticles was added to solvent of ethanol and acetic acid at a 20:1 volume to volume ratio and then mixed with a polymeric binder (e.g., from about 0.3 wt % to about −0.66 wt %) in an ultrasonic bath for 30 min. Then the solution was spin coated (e.g., step 64) on a plasma cleaned glass substrate (e.g., the wafer 14) at 1000 RPM to form an adhesion coating (e.g., the adhesion layer 42). The glass was an alkaline earth boro-aluminosilicate glass sold under the tradename Eagle® from Corning Incorporated®. The sample including the adhesion coating was calcined at 500° C. for 2 hours (e.g., step 72). The calcining was carried out in air at room temperature. X-Ray Diffraction (XRD) measurements showed Mn₃O₄ to be the primary major manganese oxide phase within the adhesion coating at the interface with the glass substrate. Further, the XRD analysis showed the substrate contained Na₄Mn₉O₁₈ and (Al,Mn)₂(SiO₄)O due to interaction with the adhesion coating. As such, it was shown that the adhesion coating had bonded with the glass substrate.

After calcining, electroless plating to form a metal coating (e.g., the conductive layer 80) was carried out using a commercial bath. The electroless plating involved the deposition of a Pd catalyst on the calcined adhesion coating followed by activation and reduction of the Pd catalyst and the electroless plating of the metal coating. The metal coating was Cu. The thickness of the metal coating formed by electroless plating was between from about 100 nm to about 150 nm. Depicted in FIG. 4A is an image of the metal coating on top of the adhesion coating after formation.

Following electroless plating, the substrate including the metal coating was thermally treated (e.g., step 84) at 400° C. for 10 min at a slow ramp rate of 1° C. per minute. The thermal treatment of the metal coating of Cu on the adhesion coating of MnOₓ at the elevated temperature of 400° C. created a Cu-Mn intermix layer due to the MnOₓ of the adhesion coating shifting oxidation states to bond with the Cu of the metal coating. Depicted in FIG. 4B is the result of thermal treatment of the metal coating on top of the adhesion coating.

After the thermal treatment, the metal coating was reduced (e.g., step 88) in forming gas (e.g., the reducing agent 90). The forming gas was a mixture of N₂ and H₂. Reduction of the metal coating in the forming gas produced a surface with sufficient electrical conductivity for electroplating (e.g., step 92). A Cu layer (e.g., the metallic component 38) was then electroplated onto the metal coating using a 1M CuSO₄ bath resulting in a 2.5 μm electroplated Cu layer. The Cu layer was then annealed under vacuum at 350° C. (e.g., step 100).

Referring now to FIG. 4C, the resulting sample of the First Example passed both a 3 N/cm and a 5 N/cm tape test. The 3 N/cm and the 5 N/cm tapes tests were performed consistent with ASTM D3359-09, without cross-hatching, where a pressure-sensitive tape is applied to the electroplated Cu layer and then removed. The electroplated Cu layer remained intact with the substrate indicating that the adhesion coating had provided sufficient bonding between the metal coating and the substrate to withstand the pulling force of the tape being removed.

Referring now to FIG. 4D, another sample prepared according to the above-described experimental procedure for the First Example passed a crosshatched tape test performed consistent with ASTM D3359-09. During the testing, a lattice pattern of cuts in perpendicular directions was made in the electroplated Cu layer and a pressure-sensitive tape was applied over the lattice and then removed. The electroplated Cu layer remained intact with the substrate indicating that the adhesion coating had provided sufficient bonding between the electroplated Cu layer and the substrate to withstand the pulling force of the tape being removed despite the cuts being present in the electroplated Cu layer. The success of the First Example is believed to have been achieved due to the MnOₓ of the adhesion coating to chemically bond with the glass (i.e., covalent bonding) and the metal coating which resulted in greater adhesion strength than offered by only the mechanical bonding of the Comparative Example. Further, as the Cu layer is electroplated onto the metal coating, the Cu layer had sufficient chemical bonding with the metal coating to resist separating from the metal coating.

Referring now to FIGS. 5A and 5B, depicted is a Second Example consistent with the present disclosure. FIGS. 5A and 5B depict a sample (e.g., the article 10) on which an adhesion coating (e.g., the adhesion layer 42) is formed. The adhesion coating was forming using a sol-gel approach and a 0.2M MnOₓ solution. The sol-gel was prepared by: 1) dissolving 9.80 g of manganese acetate hydrate and 16.81 g of citric acid monohydrate into 195.68 g of deionized water; 2) stirring overnight until precipitation was completed and a white cloudy solution was formed (pH was checked to be 2.7); 3) adjusting the pH of the solution to 9 by adding concentrated ammonium hydroxide drop by drop until a clear brownish solution was formed. A thin layer of the solution was deposited on a 2″ by 2″ glass substrate by dip coating. The glass was an alkaline earth boro-aluminosilicate glass sold under the tradename Eagle® from Corning Incorporated®. The glass substrate including the solution was then dried at 80° C. for 1 hour (i.e., to form a gel) (i.e., step 64) and calcined at 400° C. for 1 hour (i.e., step 72) with a heating rate of 0.2° C. per minute and a cooling rate of 2° C. per minute. Following the calcining, the sample then underwent electroless Cu plating, thermal treatment, reduction, electroplating and annealing steps performed in a substantially similar manner to that described with the First Example.

Referring now to FIG. 5A, the resulting sample of Second Example passed a 3 N/cm tape test. The 3 N/cm tapes test was performed consistent with ASTM D3359-09, without cross-hatching, where a pressure-sensitive tape is applied to the sample and then removed. An electroplated Cu layer of the sample remained intact with the substrate indicating that the adhesion coating formed through the sol-gel process had provided sufficient bonding between the Cu layer and the substrate to withstand the pulling force of the tape being removed.

Referring now to FIG. 5B, another sample prepared according to the above-described experimental procedure for the Second Example passed a crosshatched tape test performed consistent with ASTM D3359-09. During the testing, a lattice pattern of cuts in perpendicular directions was made in the electroplated Cu layer and a pressure-sensitive tape was applied over the lattice and then removed. The electroplated Cu layer remained intact with the substrate indicating that the adhesion coating had provided sufficient bonding between the electroplated Cu layer and the substrate to withstand the pulling force of the tape being removed despite the cuts being present in the electroplated Cu layer. The success of the Second Example is believed to have been achieved due to the same success reasons attributed to the First Example.

Clause 1 of the present disclosure extends to:
A method of forming an article, comprising:
   forming an adhesion layer comprising MnOₓ on a wafer, the wafer comprising glass, a glass-ceramic or a ceramic;
   calcining the adhesion layer, the calcining comprising heating the adhesion layer to form a calcined adhesion layer, the calcined adhesion layer comprising a chemical bond between the MnOₓ and the wafer; and
   depositing a conductive layer on the calcined adhesion layer, the conductive layer comprising a first metal.

Clause 2 of the present disclosure extends to:
The method of clause 1, wherein the wafer comprises glass.

Clause 3 of the present disclosure extends to:
The method of either of clauses 1 and 2, wherein the conductive layer comprises a thickness of from about 50 nm to about 50 μm.

Clause4 of the present disclosure extends to:
The method of any of clauses 1-3, wherein the first metal comprises Cu.

Clause 5 of the present disclosure extends to:
The method of any of clauses 1-4, wherein the depositing a conductive layer comprises electroless deposition of the first metal.

Clause 6 of the present disclosure extends to:
The method of any of clauses 1-5, wherein the calcining comprises heating the adhesion layer to a temperature in the range from 200° C. to 800° C.

Clause 7 of the present disclosure extends to:
The method of any of clauses 1-6, wherein the calcined adhesion layer comprises Mn in two or more oxidation states.

Clause 8 of the present disclosure extends to:
The method of any of clauses 1-7, wherein the wafer comprises a via and the forming an adhesion layer comprises forming the adhesion layer on a sidewall of the via.

Clause 9 of the present disclosure extends to:
The method of clause 8, wherein the via has an aspect ratio greater than 3:1.

Clause 10 of the present disclosure extends to:
The method of clause 8 or 9, wherein the sidewall has a length in a direction normal to a surface of the wafer and the adhesion layer directly contacts the sidewall along an entirety of the length.

Clause 11 of the present disclosure extends to:
The method of any of clauses 8-10, wherein the via is a blind via.

Clause 12 of the present disclosure extends to:
The method of any of clauses 8-11, wherein the adhesion layer and the conducive layer fill the via.

Clause 13 of the present disclosure extends to:
The method of any of clauses 1-12, further comprising thermal treatment of the conductive layer, the thermal treatment forming an intermix layer, the intermix layer comprising the first metal in an oxidized state and a portion of the MnOₓ.

Clause 14 of the present disclosure extends to:
The method of clause 13, wherein the thermal treatment comprises heating at a temperature greater than 300° C.

Clause 15 of the present disclosure extends to:
The method of clause 14, wherein the thermal treatment persists for at least 10 min.

Clause 16 of the present disclosure extends to:
The method of any of clauses 13-15, wherein the thermal treatment comprises increasing a temperature of the conductive layer at a rate in the range from 0.1° C./min to 2.0° C./min.

Clause 17 of the present disclosure extends to:
The method of any of clauses 13-16, wherein the metal in an oxidized state is chemically bonded to the portion of the MnOₓ.

Clause 18 of the present disclosure extends to:
The method of any of clauses 13-17, further comprising exposing the intermix layer to a reducing agent, the reducing agent reducing the first metal in an oxidized state to a neutral state.

Clause 19 of the present disclosure extends to:
The method of any of clauses 1-18, further comprising electroplating a second metal on the conductive layer.

Clause 20 of the present disclosure extends to:
The method of clause 19, further comprising annealing the second metal.

Clause 21 of the present disclosure extends to:
The method of clause 19 or 20, wherein the second metal comprises the first metal.

Clause 22 of the present disclosure extends to:
The method of any of clauses 1-21, wherein the forming an adhesion layer comprises applying a solution to the wafer, the solution comprising a compound containing Mn and O.

Clause 23 of the present disclosure extends to:
The method of clause 22, wherein the compound comprises MnOₓ in the form of nanoparticles, the nanoparticles having a D50 largest length dimension of from about 10 nm to about 500 nm.

Clause 24 of the present disclosure extends to:
The method of clause 22, wherein the compound comprises Mn bonded to an organic group.

Clause 25 of the present disclosure extends to:
The method of clause 24, wherein the organic group is an acetate group or an alkoxy group.

Clause 26 of the present disclosure extends to:
The method of any of clauses 22-25, wherein the forming an adhesion layer comprises a sol-gel process.

Clause 27 of the present disclosure extends to:
An article comprising:
   a wafer, the wafer comprising a via, the via having a sidewall; and
   a layer of MnOₓ in direct contact with the sidewall.

Clause 28 of the present disclosure extends to:
The article of clause 27, wherein the wafer comprises a glass, a glass ceramic, or a ceramic.

Clause 29 of the present disclosure extends to:
The article of clause 27 or 28, wherein the layer of MnOₓ is chemically bonded to the sidewall.

Clause 30 of the present disclosure extends to:
The article of any of clauses 27-29, wherein the layer of MnOₓ is in direct contact with an entirety of the sidewall.

Clause 31 of the present disclosure extends to:
The article of any of clauses 27-30, wherein the article further comprises an intermix layer in direct contact with the layer of MnOₓ the intermix layer comprising a first metal in an oxidized state interspersed within a portion of the MnOₓ.

Clause 32 of the present disclosure extends to:
The article of clause 31, wherein the first metal in an oxidized state is chemically bonded to the portion of the MnOₓ.

Clause 33 of the present disclosure extends to:
The article of clause 31 or 32, wherein the intermix layer further comprises the first metal in a neutral state.

Clause 34 of the present disclosure extends to:
The article of any of clauses 31-33, further comprising a layer of a second metal in direct contact with the intermix layer.

Clause 35 of the present disclosure extends to:
The article of clause 34, wherein the second metal comprises the first metal.

Clause 36 of the present disclosure extends to:
The article of any of clauses 31-35, wherein the first metal is Cu.

Modifications of the disclosure will occur to those skilled in the art and to those who make or use the disclosure. Therefore, it is understood that the embodiments shown in the drawings and described above are merely for illustrative purposes and not intended to limit the scope of the disclosure, which is defined by the following claims, as interpreted according to the principles of patent law, including the doctrine of equivalents.

It is also important to note that the construction and arrangement of the elements of the disclosure, as shown in the exemplary embodiments, is illustrative only. Although only a few embodiments of the present innovations have been described in detail in this disclosure, those skilled in the art who review this disclosure will readily appreciate that many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter recited. For example, elements shown as integrally formed may be constructed of multiple parts, or elements shown as multiple parts may be integrally formed, the operation of the interfaces may be reversed or otherwise varied, the length or width of the structures, and/or members, or connectors, or other elements of the system, may be varied, and the nature or number of adjustment positions provided between the elements may be varied. It should be noted that the elements and/or assemblies of the system may be constructed from any of a wide variety of materials that provide sufficient strength or durability, in any of a wide variety of colors, textures, and combinations. Accordingly, all such modifications are intended to be included within the scope of the present innovations. Other substitutions, modifications, changes, and omissions may be made in the design, operating conditions, and arrangement of the desired and other exemplary embodiments without departing from the spirit of the present innovations.

What is claimed is:

1. A method of forming an article, comprising:
forming an adhesion layer comprising MnOₓ on a wafer, the wafer comprising glass, a glass-ceramic or a ceramic;
calcining the adhesion layer, the calcining comprising heating the adhesion layer to form a calcined adhesion layer, the calcined adhesion layer comprising a chemical bond between the MnOₓ and the wafer; and
depositing a conductive layer on the calcined adhesion layer, the conductive layer comprising a first metal.

2. The method of claim 1, wherein the wafer comprises glass.

3. The method of claim 1, wherein the conductive layer comprises a thickness of from about 50 nm to about 50 μm.

4. The method of claim 1, wherein the first metal comprises Cu.

5. The method of claim 1, wherein the depositing a conductive layer comprises electroless deposition of the first metal.

6. The method of claim 1, wherein the calcining comprises heating the adhesion layer to a temperature in the range from 200° C. to 800° C.

7. The method of claim 1, wherein the calcined adhesion layer comprises Mn in two or more oxidation states.

8. The method of claim 1, wherein the wafer comprises a via and the forming an adhesion layer comprises forming the adhesion layer on a sidewall of the via.

9. The method of claim 8, wherein the sidewall has a length in a direction normal to a surface of the wafer and the adhesion layer directly contacts the sidewall along an entirety of the length.

10. The method of claim 1, further comprising thermal treatment of the conductive layer, the thermal treatment forming an intermix layer, the intermix layer comprising the first metal in an oxidized state and a portion of the MnOₓ.

11. The method of claim 10, further comprising exposing the intermix layer to a reducing agent, the reducing agent reducing the first metal in an oxidized state to a neutral state.

12. The method of claim 1, wherein the forming an adhesion layer comprises applying a solution to the wafer, the solution comprising a compound containing Mn and O.

13. The method of claim 12, wherein the compound comprises MnOₓ in the form of nanoparticles, the nanoparticles having a D50 largest length dimension of from about 10 nm to about 500 nm.

14. The method of claim 12, wherein the compound comprises Mn bonded to an organic group.

15. An article comprising:
a wafer, the wafer comprises a glass, a glass ceramic, or a ceramic, the wafer further comprising a via, the via having a sidewall; and
a layer of MnOₓ in direct contact with the sidewall.

16. The article of claim 15, wherein the layer of MnOₓ is chemically bonded to the sidewall.

17. The article of claim 15, wherein the article further comprises an intermix layer in direct contact with the layer of MnOₓ, the intermix layer comprising a first metal in an oxidized state interspersed within a portion of the MnOₓ.

18. The article of claim 17, wherein the first metal in an oxidized state is chemically bonded to the portion of the MnOₓ.

19. The article of claim 17, wherein the intermix layer further comprises the first metal in a neutral state.

20. The article of claim 17, wherein the first metal is Cu.
